(19) United States
(12) Patent Application Publication
(10) Pub. No.: US 2026/0122971 A1
(43) Pub. Date: Apr. 30, 2026

(54) Transistors with Tin Oxide Semiconductor and Nucleation Layer

(71) Applicant: Zinite Corporation, Vancouver (CA)

(72) Inventors: Fenglin Liu, Edmonton (CA); Gem Shoute, Edmonton (CA); Douglas Barlage, Edmonton (CA)

(21) Appl. No.: 19/373,327

(22) Filed: Oct. 29, 2025

Related U.S. Application Data
(60) Provisional application No. 63/713,853, filed on Oct. 30, 2024.

(51) Int. Cl. H10D 30/67; H10D 30/01; H10D 62/40

(52) U.S. Cl. CPC H10D 30/6755; H10D 30/0314; H10D 30/6706; H10D 30/6731; H10D 30/6736; H10D 30/6757; H10D 62/405

(57) ABSTRACT

An example thin-film transistor includes a silicon-based substrate and a source and drain at the silicon-based substrate. The source and drain are spaced apart by a gap. The thin-film transistor further includes a nucleation layer in contact with at least the silicon-based substrate within the gap, and a body of channel material in contact with the nucleation layer. The channel material is nanocrystalline tin oxide (SnO₂). The nucleation layer includes a nucleation element that may reduce thermally induced stress between the silicon-based substrate and the body of channel material. The nucleation element may also promote a preferred crystal orientation for the channel material.

### RELATED APPLICATION

The present application claims priority to U.S. Provisional Patent Application No. 63/713,853, filed Oct. 30, 2024, and entitled “Transistors with Tin Oxide Semiconductor,” which is hereby incorporated by reference in its entirety.

### FIELD

The present disclosure relates to transistors that have metal-oxide semiconductors.

### BACKGROUND

The manufacture and operation of transistors, such as thin-film transistors (TFTs), are heavily dependent on the materials used. The choice of semiconductor and the process to form such influences various characteristics of a TFT, such as carrier mobility, stability, and so on.

### SUMMARY

The present disclosure relates generally to a thin-film transistor, substantially as illustrated by and described in connection with at least one of the figures, as set forth more completely in the claims.

### BRIEF DESCRIPTION OF THE DRAWINGS

The foregoing and other objects, features, and advantages of the devices, systems, and methods described herein will be apparent from the following description of particular embodiments thereof, as illustrated in the accompanying figures, where like reference numbers refer to like structures. The figures are not necessarily to scale, emphasis instead being placed upon illustrating the principles of the devices, systems, and methods described herein.

FIG. 1 is a cross-sectional view of an example thin-film transistor with a tin oxide semiconductor layer and a nucleation layer according to the present disclosure.

FIG. 2 is a cross-sectional view of an example thin-film transistor with a tin oxide semiconductor layer and treated source/drain according to the present disclosure.

FIG. 3A is a plot of example preferred crystal orientations for a 40 nm tin oxide thin film according to the present disclosure.

FIG. 3B is a plot of example preferred crystal orientations for a 20 nm tin oxide thin film according to the present disclosure.

FIG. 4 is a flowchart of an example method of making a thin-film transistor with a tin oxide semiconductor layer and a nucleation layer according to the present disclosure.

FIG. 5 is a plot of a capacitance-voltage (C-V) dot test for an example tin oxide semiconductor layer according to the present disclosure.

### DETAILED DESCRIPTION

References to items in the singular should be understood to include items in the plural, and vice versa, unless explicitly stated otherwise or clear from the text. Grammatical conjunctions are intended to express any and all disjunctive and conjunctive combinations of conjoined clauses, sentences, words, and the like, unless otherwise stated or clear from the context. Recitation of ranges of values herein are not intended to be limiting, referring instead individually to any and all values falling within the range, unless otherwise indicated herein, and each separate value within such a range is incorporated into the specification as if it were individually recited herein. In the following description, it is understood that terms such as “first,” “second,” “top,” “bottom,” “side,” “front,” “back,” and the like are words of convenience and are not to be construed as limiting terms unless otherwise stated or clear from context.

As used herein, the terms “about,” “approximately,” “substantially,” or the like, when accompanying a numerical value, are to be construed as indicating a deviation as would be appreciated by one of ordinary skill in the art to operate satisfactorily for an intended purpose. Ranges of values and/or numeric values are provided herein as examples only, and do not constitute a limitation on the scope of the described embodiments. The use of any and all examples, or exemplary language (“e.g.,” “such as,” or “the like”) provided herein, is intended merely to better illuminate the embodiments and does not pose a limitation on the scope of the embodiments. The terms “e.g.,” and “for example” set off lists of one or more non-limiting examples, instances, or illustrations. No language in the specification should be construed as indicating any unclaimed element as essential to the practice of the embodiments.

As used herein, the term “and/or” means any one or more of the items in the list joined by “and/or.” As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y, and/or z” means “one or more of x, y, and z.”

As used herein, the terms “exemplary” and “example” mean “serving as an example, instance or illustration.” The embodiments described herein are not limiting, but rather are exemplary only. It should be understood that the described embodiments are not necessarily to be construed as preferred or advantageous over other embodiments. Moreover, the terms “embodiments of the invention,” “embodiments,” or “invention” do not require that all embodiments of the invention include the discussed feature, advantage or mode of operation.

The present disclosure relates to the use of tin oxide (SnO₂) as a semiconductor channel material for various transistors, such as TFTs. It has been discovered that certain polycrystalline, and more specifically nanocrystalline, structures of tin oxide are particularly useful in improving carrier mobility and stability, and that nanocrystalline structures of tin oxide may be formed more effectively and be given improved characteristics with the use of a nucleation layer. For instance, the nucleation layer may reduce thermal stresses at an interface between the channel material and a substrate and may promote a desired crystal structure of the channel material.

According to an aspect of the present disclosure, a thin-film transistor includes a silicon-based substrate and a source and drain at the silicon-based substrate. The source and drain are spaced apart by a gap. The thin-film transistor further includes a nucleation layer in contact with at least the silicon-based substrate within the gap, and a body of channel material in contact with the nucleation layer. The channel material is nanocrystalline tin oxide (SnO₂). The nucleation layer includes a nucleation element that reduces thermally induced stress between the silicon-based substrate and the body of channel material.

The nucleation element may be silicon.

The nucleation layer may include silicon dioxide and tin oxide (SnO₂).

The nucleation layer may include a gradient from silicon dioxide at the silicon-based substrate to tin oxide (SnO₂) at the body of channel material.

The nucleation element may be selected from the group consisting of germanium, hafnium, zirconium, and titanium.

The nucleation element may promote a preferred crystal orientation for the channel material.

The preferred crystal orientation may be Miller index <110>.

According to an aspect of the present disclosure, a method of forming a thin-film transistor includes forming a nucleation layer in contact with a silicon-based substrate and forming a source and drain at the nucleation layer. The source and drain are spaced apart by a gap. The method further includes forming a body of channel material in contact with at least the nucleation layer in the gap. The channel material is nanocrystalline tin oxide (SnO₂). Preferably, the nucleation layer includes a nucleation element that reduces thermally induced stress between the silicon-based substrate and the body of channel material.

The nucleation element may be silicon.

The nucleation layer may include silicon dioxide and tin oxide (SnO₂).

Forming the nucleation layer may include forming a gradient from silicon dioxide at the silicon-based substrate to tin oxide (SnO₂) at the body of channel material.

Forming the nucleation layer may include using atomic layer deposition.

Forming the gradient of the nucleation layer may include controlling relative doses of silicon and tin precursors over a sequence of deposition cycles.

Forming the gradient of the nucleation layer may include forming alternating sub-layers of silicon dioxide and tin oxide (SnO₂).

The nucleation element may be selected from the group consisting of germanium, hafnium, zirconium, and titanium.

Forming the nucleation layer may include using sputtering.

The nucleation element may promote a preferred crystal orientation for the channel material.

The preferred crystal orientation may be Miller index <110>.

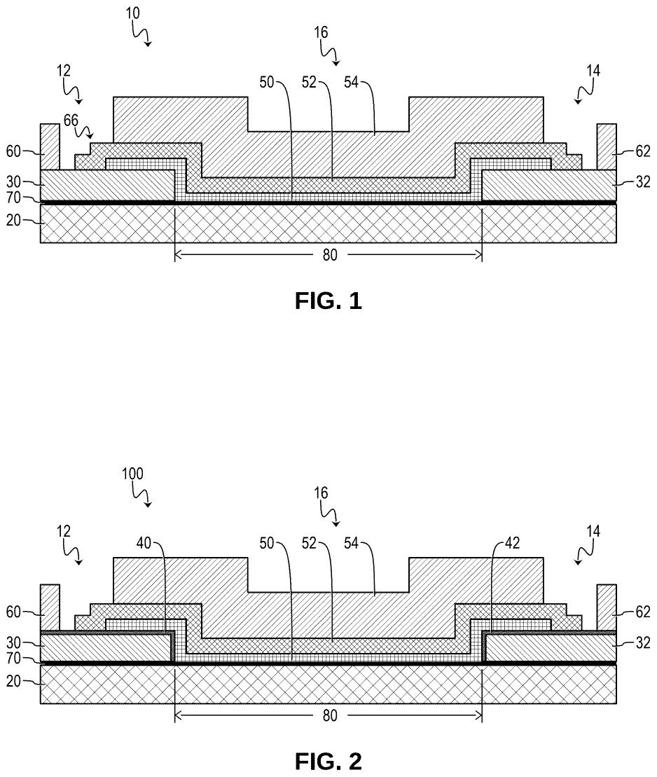

FIG. 1 shows an example TFT 10 according to the present disclosure. The TFT 10 includes a source 12, drain 14, and gate 16.

The TFT 10 is formed with a planar substrate 20. The substrate 20 may be disposed over another layer of TFTs, whether manufactured in accordance with the present disclosure or by another technique, or over a layer of complementary metal-oxide-semiconductor (CMOS) devices or other front end of line (FEOL) devices. In some embodiments, the TFT 10 may be manufactured using back end of line (BEOL) and/or middle of line (MOL) processes.

Examples of materials for the substrate 20 include silicon-based materials, such as silicon dioxide; silicon nitride; glass; fluorosilicate glass (FSG); or a silicon wafer whose surface is processed with wet thermal oxide (WTO) or similar treatment. The substrate 20 may be referred to as a base layer.

In various examples, the substrate 20 is a {100} p-type boron-doped silicon wafer (0.01-0.02 Ω·cm) with about 500 nm of grown WTO, on which a thin layer (about 7-8 nm) of silicon dioxide is formed.

A nucleation layer 70 is formed in contact with the substrate 20. The nucleation layer 70 includes silicon, germanium, or similar element and will be discussed in further detail below.

The source 12 is formed over the nucleation layer 70 and includes a body of source material 30.

Examples of source materials include various metals or other conductors, such as nickel, tungsten, ruthenium, molybdenum, copper, cobalt, titanium nitride, etc. Further examples of source materials include heavily doped n-type materials, degenerate n-type silicon, and III-V compound semiconductors with high conductivity with predominately n-type or electron transport, etc.

In this example, the body of source material 30 is ruthenium that is formed by sputtering to a thickness of about 25 nm.

The drain 14 is formed over the nucleation layer 70 and space apart by a gap 80 from the source 12. The drain 14 includes a body of drain material 32. In this example, the drain 14 has the same or similar material and/or structure as the source 12. In other examples, the drain 14 has a material and/or structure different to the source 12.

The TFT 10 further includes a body of channel material 50 disposed in the gap 80 between the source 12 and drain 14. In this example, the body of channel material 50 is disposed partially over the bodies of source and drain material 30, 32 and in contact with the nucleation layer 70 between the bodies of source and drain material 30, 32. The channel material is a layer tin dioxide (i.e., SnO₂, also referred to herein as “tin oxide”) that may have a thickness of about 5 nm to about 10 nm. In this example, the layer of tin oxide is about 7 nm thick.

The TFT 10 further includes a body of gate dielectric material 52 disposed over the body of channel material 50. Examples of gate dielectric materials include high-K dielectric materials, hafnium oxide, silicon dioxide, silicon nitride, zirconium oxide, and aluminum oxide. In this example, the body of gate dielectric material 52 is a layer of hafnium oxide about 12.5 nm thick.

The TFT 10 further includes a body of gate material 54 (also termed “gate metal”) disposed over the gate dielectric material 54. The gate material is a conductor. Examples of gate materials include tungsten, titanium, titanium nitride, molybdenum, gold, platinum, aluminum, nickel, copper, chromium, hafnium, indium, manganese, iron, vanadium, zinc, tantalum, or alloys/combinations thereof. Suitable combinations of such materials may also be used. In this example, the body of gate material 54 is a layer of tungsten about 30 nm thick.

The TFT 10 further includes a source electrode 60 as part of the source 12 and a drain electrode 62 as part of the drain 14. The source electrode 60 is in electrical contact with the body of source material 30 to provide current to the body of source material 30. Likewise, the drain electrode 62 is in electrical contact with the body of drain material 32 to receive current to the body of source drain 32. Examples of materials for electrodes 60, 62 include the gate materials listed above.

In operation, when a voltage is applied across the source electrode 60 and a drain electrode 62, and when a suitable voltage is applied to the body of gate material 54, a carrier channel forms in the body of channel material 50, which causes the flow of current between the source 12 to the drain 14.

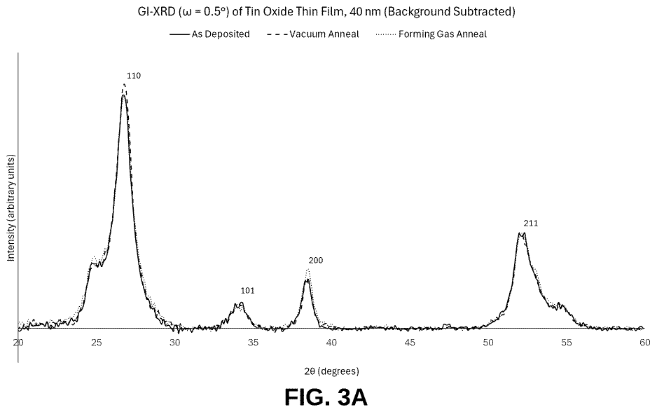

FIG. 2 shows another example TFT 100 according to the present disclosure. The TFT 100 is substantially the same as the TFT 10 except that source and drain channel interfaces 40, 42 are provided. The above description may be referenced for details not repeated below.

The body of source material 30 may be subject to inline treatment, such as plasma treatment, anneal treatment, chemical or electro-chemical treatment, or similar. Different types of treatment may be combined. A treatment may be repeated two or more times.

The treatment may form a p-type or n-type source-channel interface 40 at the body of source material 30 and between the body of source material 30 and channel material 50. The source-channel interface 40 may tune the threshold voltage at which TFT 100 turns on, making the transistor operate in enhancement or depletion mode, to reduce leakage current through TFT 100 in the off state. The source-channel interface 40 may create a repository of complimentary excess positive or negative charge that functions to deplete the channel in at least the region of the body of channel material 50 adjacent the body of source material 30. In this manner, the source-channel interface 40 serves as a voltage-controlled electron transport barrier, resulting in substantially less current flow through body of channel material 50 when TFT 100 is in an off state. Further, the source-channel interface 40 may also serve to reduce stress induced leakage currents (“SILC”) in TFT 100 by inhibiting the formation of interlayer stress-induced flaws between the body of channel material 50 and the body of source material 30. A drain-channel interface 42 may be similarly formed and may have similar characteristics, but it is contemplated that the source-channel interface provides 40 a significant benefit without the drain-channel interface 42 and may provide most or all of the benefit.

In this example, the bodies of source and drain material 30, 32 are treated with oxygen plasma to form a layer of oxidized material that are the source and drain channel interfaces 40, 42.

Further reference may be made to U.S. Pat. No. 11,949,019, which is incorporated herein by reference.

As mentioned above, in the TFTs 10, 100, the body of channel material 50 is a thin film of tin oxide. The tin oxide is generally polycrystalline, and more specifically nanocrystalline, with a preferred crystallite orientation of Miller index <110>, as determined using grazing-incidence x-ray diffraction (GI-XRD) with @=0.5° on 40 nm thick samples. It has been discovered that nanocrystalline tin oxide with this preferred crystal orientation provides good carrier mobility and good stability, which improves the performance and useful life of the TFT 10, 100. The proportion of the thin film of tin oxide of orientation of <110> is preferably at least about 45%, more preferably at least about 50%, and still more preferably at least about 55%.

For sake of clarity, tin oxide with an orientation of <110> means that one of the directions in the family of directions <110>, such as direction [110], is substantially normal to the plane of the substrate 20. In other words, a plane of the family {110}, such as the plane (110), is substantially parallel to the plane of the substrate 20.

The crystallinity of the thin film of tin oxide is preferably at least about 80%, more preferably at least about 85%, more preferably at least about 90%, and still more preferably at least about 95%. Regions outside the 20 angular range of 20-60° may be ignored when computing crystallinity.

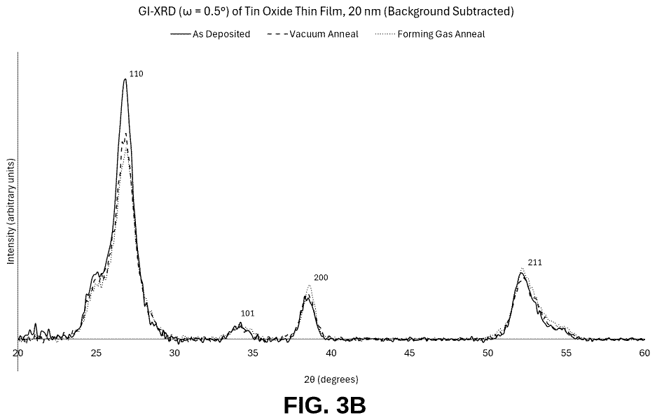

FIG. 3A shows GI-XRD (ω=0.5°) plots of 40 nm thick samples of tin oxide thin film made according to this disclosure. Three samples are plotted, namely, tin oxide as deposited, as annealed under vacuum at 400° C. for 60 minutes, and after undergoing forming gas anneal at 400° C. for 120 minutes. As can be seen, the plots generally follow the XRD pattern of cassiterite. The ratios of peak intensities of different crystal orientations with <110> as a basis value of 1 are listed below in Table 1.

TABLE 1
Peak Intensity Ratios for Tin Oxide Crystal
Orientations with <110> as Basis

| Orientation | 110 | 101 | 200 | 211 |
|---|---|---|---|---|
| As Deposited | 1 | 0.11 | 0.21 | 0.41 |
| Vacuum Anneal | 1 | 0.10 | 0.21 | 0.39 |
| Forming Gas Anneal | 1 | 0.10 | 0.25 | 0.41 |

FIG. 3B shows GI-XRD (ω=0.5°) plots of 20 nm thick samples of tin oxide thin film made according to this disclosure. Three samples are plotted, namely, tin oxide as deposited, as annealed under vacuum at 400° C. for 60 minutes, and after undergoing forming gas anneal at 400° C. for 120 minutes. As can be seen, the plots are consistent with the 40 nm samples of FIG. 3A.

Peak intensity ratios may be used to describe the tin oxide thin films discussed herein. For example, with reference to Table 1, the ratio of crystal-orientation peak intensities of Miller index <101>:<110> is 0.11:1, as deposited. A ratio that is less would be 0.10:1, 0.09:1, etc. Expressions of such ratios that describe the tin oxide thin films discussed herein are provided in the Summary section above.

It is important to note that GI-XRD measurements were performed on 20 nm and 40 nm thick films of tin oxide to provide sufficient accuracy, as the GI-XRD technique loses accuracy as film thickness decreases. While 20 nm and 40 nm are considerably thicker than the body of channel material 50 (about 5-10 nm, e.g., 7 nm) discussed above, GI-XRD may still be used to establish useful process parameters. Process parameters may be established by having a thicker film, such as 20 nm or 40 nm, take the preferred crystal orientation. A thinner film, such as 7 nm, may then be deposited using these established process parameters. If the thinner film performs sufficiently well, then the process parameters are useful. While it is contemplated that the thinner film will have the same or similar crystal orientation as the thicker film, this need not be confirmed with measurement.

Resistivity of the thin film of tin oxide has been found to be in the range of about 0.001-1 Ω·cm, as deposited. Annealing at 400° C. for at least 30 minutes in air, nitrogen, or forming gas reduced resistivity to the range of about 0.001-0.1 Ω·cm. Annealing at 400° C. for at least 30 minutes in nitrogen or forming gas reduced resistivity to the range of about 0.001-0.01 Ω·cm. Resistivity of the thin film of tin oxide is preferably less than about 0.0050 Ω·cm, more preferably less than about 0.0040 Ω·cm, and still more preferably less than or equal to about 0.0036 Ω·cm.

The crystallinity and preferred orientation of the tin oxide thin film help achieve high carrier mobility. High crystallinity leads to fewer defects and grain boundaries, reducing obstacles for carrier movement and thus improving mobility. Aligning the crystalline grains in the preferred orientation discussed herein further enhances carrier transport. Mobility of the thin film of tin oxide has been found to be in the range of about 60-120 cm²/V·s. Mobility is preferably at least about 70 cm²/V·s, more preferably at least about 100 cm²/V·s, more preferably at least about 100 cm²/V·s, and still more preferably at least above 120 cm²/V·s.

Other chemical species may be included in the tin oxide (e.g., by doping) to improve stability, carrier concentration, conductance, or other property. For example, fluorine, chlorine, nitrogen, or similar material may be introduced to the tin oxide. In the example of chlorine, chlorine atoms may replace oxygen atoms in the tin oxide. Chlorine may be present in concentrations (relative to oxygen) of about 10% or less, preferably about 5% or less, more preferably about 2% or less, more preferably about 1% or less, and still more preferably about 0.7%. Alternatively, fluorine or nitrogen may be introduced at the same proportions.

In various examples, the thin film of tin oxide has minimal deleterious elements or species between grain boundaries that would inhibit the transport of carriers to less than about 50% of the maximum conductance.

In various examples, the thin film of tin oxide has a carrier concentration of less than about 2.5×10¹⁹ cm⁻³ as extracted from a capacitance-voltage testing method that uses a vertical, parallel-plate capacitor test structure.

In various examples, the thin film of tin oxide withstands forming gas or other hydrogen condition up to about 550° C. with its carrier concentration not increasing more than two-fold.

TFT 10, 100 may be manufactured using FEOL processes, MOL processes, BEOL processes, or a combination of such. A manufacturing process may include forming one or more layers of TFTs 10, 110 over other devices made using FEOL, MOL, and/or BEOL processes.

The manufacture of materials, layers, and/or features of semiconductor devices is referred to herein as “forming.” As will be apparent to those of ordinary skill in the art, unless otherwise mentioned, “forming” is intended to include all semiconductor manufacturing techniques suitable and applicable therefor including, without limitation, deposition (e.g., chemical vapor deposition or CVD, atomic layer deposition or ALD, physical vapor deposition or PVD, etc.), plasma-enhanced/assisted atomic layer deposition (PEALD/PAALD), thermal ALD (T-ALD), plasma-enhanced chemical vapor deposition (PECVD), sputtering, lithography/photolithography, etching, implantation, annealing, oxidation, and similar processes. While examples of specific types of forming are given below, it should be understood that comparable methods of forming may be alternatively or additionally used, unless otherwise mentioned, without departing from the present disclosure.

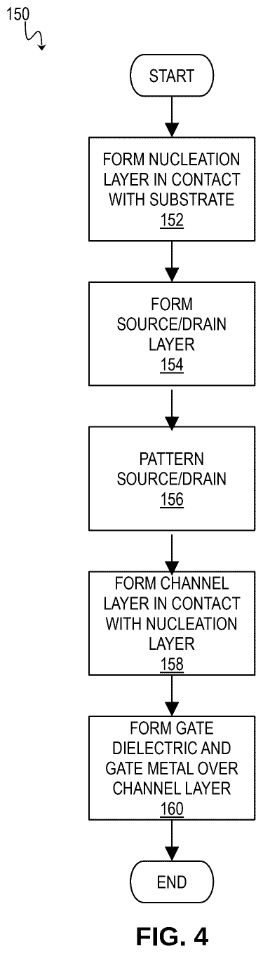

FIG. 4 shows an example method 150 of making a TFT, such as a TFT 10, 100, with a tin oxide semiconductor layer formed over a nucleation layer.

With reference to FIGS. 1, 2, and 4, a substrate 20 may be formed as discussed above.

At block 152, prior to forming the source/drain, a nucleation layer 70 is formed at and in contact with the substrate 20. The nucleation layer 70 includes a nucleation element, such as silicon, germanium, hafnium, zirconium, titanium, or other material that has outer shell electrons sufficiently matching tin. The nucleation layer 70 may be formed by ALD, sputtering, or other suitable forming technique.

The nucleation layer 70 should be sufficiently thin to avoid unexpected/undesired interactions with other materials/structures of the TFT, but also thick enough to avoid gaps in coverage (islanding). In various examples, the nucleation layer 70 has a thickness of about 0.25 nm to about 15 nm, for example about 10 nm.

In some examples, the nucleation layer 70 is formed as a gradient from the material of the substrate 20 to the channel material 50. The nucleation layer 70 may begin as silicon dioxide (i.e., substrate material) and transition to tin oxide (i.e., channel material).

When formed by ALD or similar deposition technique, a gradient may be formed cycle-by-cycle by controlling relative precursor doses with a shared dose of oxidant. For example, during each cycle of a sequence of ALD cycles, a proportional dose of X Si-precursor and a proportional dose of 1-X Sn-precursor may be introduced with a shared dose of oxidant (e.g., oxygen plasma), where X is between 1 and 0 and is gradually decreased each cycle. An example deposition sequence may thus be as follows: cycle 1) 0.8 Si-precursor, 0.2 Sn-precursor, and oxidant; cycle 2) 0.6 Si-precursor, 0.4 Sn-precursor, and oxidant; cycle 3) 0.4 Si-precursor, 0.6 Sn-precursor, and oxidant; and cycle 4) 0.2 Si-precursor, 0.8 Sn-precursor, and oxidant. The relative proportions of Si-precursor and Sn-precursor are changed over a sequence of cycles to form a gradient, which may be fairly coarse given the thinness of the nucleation layer 70 relative to the size of the molecules involved.

Alternatively, a gradient may be formed by configuring an ALD tool or other deposition tool to deposit such materials as alternating homogenous sub-layers, as may be achieved by controlling the relative number of cycles of each material. For example, starting at a base layer of silicon dioxide, the following sequence of cycles may be used to form a gradient from sub-layers: one cycle of tin oxide, one cycle of silicon dioxide, two cycles of tin oxide, one cycle of silicon dioxide, three cycles of tin oxide, and one cycle of silicon dioxide. Subsequently the tin oxide channel layer is formed over the last sub-layer.

In other examples, the nucleation layer 70 is not a gradient. Such a nucleation layer 70 may include fixed proportions of silicon dioxide and tin oxide, which may be deposited using proportional precursor amounts or alternating sub-layers, as discussed above. In one example, ALD with a Si:Sn precursor ratio of 0.5:0.5 is used with an oxidant. In another example, alternating cycles or sub-layers of tin oxide and silicon dioxide are used. In these examples, it may be beneficial to limit the nucleation layer 70 to a maximum thickness of about 1 nm, about 0.5 nm, or about 0.25 nm, for example.

The nucleation layer 70, or at least the portion of the nucleation layer 70 that includes substantial silicon dioxide, is electrically insulating, which serves to insulate the bodies of source and drain material 30, 32 and the body of channel material 50 from the substate 20.

The nucleation layer 70 may help reduce thermally induced stress between the substrate 20 the channel material 50. Mismatch in thermal properties of the substrate 20 the channel material 50 may cause separation, delamination, strain-related failure, and/or other mechanical failure at the interface between the substrate 20 and the channel material 50.

The nucleation layer 70 may promote growth of the tin oxide (SnO₂) channel material with the preferred crystal orientation discussed above to form the body of channel material 50.

The nucleation layer 70 may also provide for gettering of oxygen and/or other undesirable species. The nucleation layer 70 may increase the speed and reliability at which the channel material 50 is formed with the desired crystal orientation.

In various examples, nitrogen may be added to the nucleation layer 70 so that silicon nitride or silicon oxynitride is formed as part of the nucleation layer. Nitrogen may further improve the characteristics of the nucleation layer, such as increasing strength and stability. Nitrogen may be introduced at about 1% to 20% (with respect to oxygen) during the forming process.

At block 154, a layer of source/drain material, such as ruthenium, is formed over and in contact with the nucleation layer 70. The source/drain material may be formed by sputtering to a desired thickness, such as about 25 nm.

At block 156, the layer of source/drain material is then patterned to form separate bodies of source and drain material 30, 32 and define a gap 80 therebetween. Lithography and etching, such as inductively coupled plasma reactive ion etching (ICP-RIE), may be used to form the bodies of source and drain material 30, 32. The nucleation layer 70 is not patterned.

In the case of TFT 100, source and drain channel interfaces 40, 42 are then formed. This may include treating the bodies of source and drain material 30, 32 with oxygen plasma to form a layer of oxidized material thereon. In various examples, plasma treatment is as follows: argon (˜95%) and hydrogen (˜5%) plasma for a duration of about 10 seconds; then oxygen plasma for a duration of about 60 seconds; and then nitrogen plasma for a duration of about 30 seconds. The treatment may be performed at 190° C. and 600 W. Remote plasma processing may be used with a carrier gas, such as argon. This sequence may be repeated two or more times.

Subsequently, at block 158, a body of channel material 50 is formed over the bodies of source and drain material 30, 32 and over the nucleation layer 70 within the gap 80 between the bodies of source and drain material 30, 32.

In this example, the body of channel material 50, i.e., tin oxide, is grown by PEALD in contact with the nucleation layer 70 and the bodies of source and drain material 30, 32 using tetraallyltin (C₁₂H₂₀Sn) as precursor with oxygen plasma. Plasma power is nominally 600 W and chamber pressure is about 1 Torr. The substrate temperature is about 190° C. and the ampoule temperature is about 82° C. Oxygen flow rate is about 60 standard cubic centimeters per minute (sccm) and argon carrier gas flow rate is about 100 sccm. A cycle is performed as follows: 0.06 seconds of precursor dose, 3 seconds of purge, 5 seconds of plasma, and 7 seconds of purge. Cycles are repeated until the desired thickness of film is obtained. In this manner, the tin oxide with preferred crystal orientation may be grown to any suitable desired thickness, such as about 7 nm. In various examples, chlorine, fluorine, nitrogen, or other stabilizing species may be introduced during the PEALD process.

In other examples, T-ALD may be used to grow the body of channel material 50.

Then, at block 160, the gate is formed.

Gate dielectric material is formed over the tin oxide channel material. This may be done in two separate deposition and patterning operations. After an initial deposition of gate dielectric material, the gate dielectric material and underlying channel material may be patterned together using the same mask. Then, to prevent the channel material from shorting to the body of gate material 54, a second layer of gate dielectric material may be deposited and patterned in a manner that encapsulates the channel material, as shown at 66 in FIG. 1. Alternatively, a single deposition and patterning operation may be used to form the gate dielectric material.

The initial layer of gate dielectric material is formed over the layer of channel material. A layer of hafnium oxide may be formed by PEALD using tetrakis(dimethylamino) hafnium (TDMAH) as precursor with oxygen plasma at about 277° C. The initial layer of hafnium oxide may be deposited to a desired thickness, such as about 5 nm.

The layers of tin oxide and hafnium oxide are then patterned. Lithography and etching, such as ICP-RIE, may be used. The same mask may be used to give the same pattern to both layers. This patterning completes the body of channel material 50.

The second layer of gate dielectric material is then formed over the patterned initial layer of gate dielectric material. PEALD may be used, as discussed above. The second layer of hafnium oxide may be deposited to a desired thickness, such as about 7.5 nm.

The second layer of gate dielectric material is then patterned. Lithography and etching, such as ICP-RIE, may be used. The pattern used to form the second layer of gate dielectric material should be larger than the pattern used to form the initial layer of gate dielectric material and channel material, so that edges of the body of channel material 50 are covered by gate dielectric material, as shown at 66 in FIG. 1. This patterning completes the body of gate dielectric material 52.

Then, a layer of gate material is formed. In this example, the layer of gate material ultimately forms the body of gate material 54 and the source and drain electrodes 60, 62. The layer of gate material may be formed by sputtering material mentioned above.

The layer of gate material may then be patterned to form the separate body of gate material 54 and source and drain electrodes 60, 62. Lithography and etching, such as ICP-RIE, may be used.

### Example

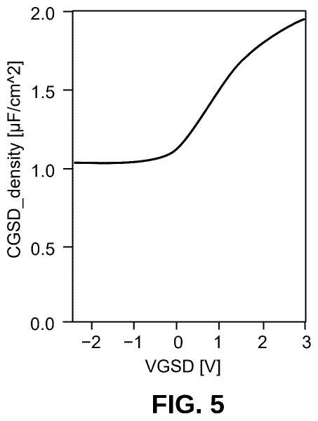

A wafer was prepared, as discussed above with regard to the substrate 20, and a thin film of tin oxide was deposited (without the nucleation layer), using the PEALD recipe discussed above, to a thickness of 7 nm. A forming gas anneal at 400° C. for 120 minutes was performed. The resulting tin oxide film was determined to have a crystallinity (2θ of 20-60°) of 95.6% with a preferred orientation (GI-XRD with ω=0.5°) of Miller index <110>. Resistivity was measured to be 0.00391 Ω·cm. Carrier mobility was measured to be 115.6 cm²/V·s. Metal-oxide semiconductor (MOS) capacitor or MOSCAP capacitance-voltage (C-V) profiling was performed with the results shown in FIG. 5.

With another film, deposited in the same manner to 10 nm, atomic force microscopy (AFM) roughness was measured to be 0.55 nm.

While particular embodiments have been shown and described, it will be apparent to those skilled in the art that various changes and modifications, in form and details, may be made without departing from the spirit and scope of this disclosure and are intended to form a part of the invention as defined by the following claims, which are to be interpreted in the broadest sense allowable by law. Further, the sequence of steps for example methods described or illustrated herein are not to be construed as necessarily requiring their performance in the particular order described or illustrated unless specifically identified as requiring so or clearly identified through context. Moreover, the example methods may omit one or more steps described or illustrated, or may include additional steps in addition to those described or illustrated. Thus, one of ordinary skill in the art, using the disclosures provided herein, will appreciate that various steps of the example methods can be omitted, rearranged, combined, and/or adapted in various ways without departing from the spirit and scope of the inventions.

What is claimed is:

1. A thin-film transistor comprising:
a silicon-based substrate;
a source and drain at the silicon-based substrate, the source and drain being spaced apart by a gap;
a nucleation layer in contact with at least the silicon-based substrate within the gap; and
a body of channel material in contact with the nucleation layer, the channel material being nanocrystalline tin oxide (SnO₂);
wherein the nucleation layer includes a nucleation element.

2. The thin-film transistor of claim 1, wherein nucleation element reduces thermally induced stress between the silicon-based substrate and the body of channel material.

3. The thin-film transistor of claim 1, wherein the nucleation element is silicon.

4. The thin-film transistor of claim 3, wherein the nucleation layer comprises silicon dioxide and tin oxide (SnO₂).

5. The thin-film transistor of claim 4, wherein the nucleation layer comprises a gradient from silicon dioxide at the silicon-based substrate to tin oxide (SnO₂) at the body of channel material.

6. The thin-film transistor of claim 1, wherein the nucleation element is selected from the group consisting of germanium, hafnium, zirconium, and titanium.

7. The thin-film transistor of claim 1, wherein the nucleation element promotes a preferred crystal orientation for the channel material.

8. The thin-film transistor of claim 7, wherein the preferred crystal orientation is Miller index <110>.

9. A method of forming a thin-film transistor, the method comprising:
forming a nucleation layer in contact with a silicon-based substrate;
forming a source and drain at the nucleation layer, the source and drain being spaced apart by a gap; and
forming a body of channel material in contact with at least the nucleation layer in the gap, the channel material being nanocrystalline tin oxide (SnO₂);
wherein the nucleation layer includes a nucleation element.

10. The method of claim 9, wherein the nucleation element reduces thermally induced stress between the silicon-based substrate and the body of channel material.

11. The method of claim 9, wherein the nucleation element is silicon.

12. The method of claim 11, wherein the nucleation layer comprises silicon dioxide and tin oxide (SnO₂).

13. The method of claim 12, wherein forming the nucleation layer comprises forming a gradient from silicon dioxide at the silicon-based substrate to tin oxide (SnO₂) at the body of channel material.

14. The method of claim 13, wherein forming the nucleation layer comprises using atomic layer deposition.

15. The method of claim 14, wherein forming the gradient of the nucleation layer comprises controlling relative doses of silicon and tin precursors over a sequence of deposition cycles.

16. The method of claim 14, wherein forming the gradient of the nucleation layer comprises forming alternating sub-layers of silicon dioxide and tin oxide (SnO₂).

17. The method of claim 9, wherein the nucleation element is selected from the group consisting of germanium, hafnium, zirconium, and titanium.

18. The method of claim 9, wherein forming the nucleation layer comprises using sputtering.

19. The method of claim 9, wherein the nucleation element promotes a preferred crystal orientation for the channel material.

20. The method of claim 19, wherein the preferred crystal orientation is Miller index <110>.
